(19) United States
(12) Patent Application Publication
(10) Pub. No.: US 2026/0179692 A1
(43) Pub. Date: Jun. 25, 2026

(54) NONVOLATILE MEMORY DEVICE FOR SELECTIVELY SKIPPING PART OF READ OPERATION ACCORDING TO TIMING OF READ COMMAND, OPERATING METHOD OF THE NONVOLATILE MEMORY DEVICE, AND STORAGE DEVICE INCLUDING THE NONVOLATILE MEMORY DEVICE

(71) Applicant: Samsung Electronics Co., Ltd., Suwon-si (KR)

(72) Inventors: Doohyun Kim, Suwon-si (KR); Yohan Lee, Suwon-si (KR)

(21) Appl. No.: 19/394,724

(22) Filed: Nov. 19, 2025

(30) Foreign Application Priority Data
Dec. 20, 2024 (KR) 10-2024-0193323

(51) Int. Cl. G11C 16/26; G11C 16/04; G11C 16/08; G11C 16/24

(52) U.S. Cl. CPC G11C 16/26; G11C 16/0483; G11C 16/08; G11C 16/24

(57) ABSTRACT

A nonvolatile memory device for selectively skipping part of a read operation based on a timing of a read command, an operating method of the nonvolatile memory device, and a storage device including the nonvolatile memory device are provided. The operating method of the nonvolatile memory device includes performing, based on a first read command, on a first selected word line, a first sensing operation that starts by a first read order indicating an order of applying at least two first read voltages, and performing, based on the second read command received after the first read command, on a second selected word line, a second sensing operation that starts by a second read order being based on a first address of the first read command and a second address of the second read command.

### CROSS-REFERENCE TO RELATED APPLICATION

This application is based on and claims priority under 35 U.S.C. § 119 to Korean Patent Application No. 10-2024-0193323, filed on Dec. 20, 2024, in the Korean Intellectual Property Office, the disclosure of which is incorporated by reference herein in its entirety.

### BACKGROUND

As a flash memory system, an example of a nonvolatile memory (or a nonvolatile memory device), a universal serial bus (USB) drive, a smartphone, a tablet personal computer (PC), a memory card, a solid state drive (SSD), etc. are widely used. For a memory system including a nonvolatile memory, it is important to have large capacitance and increased speeds of memory operations, such as read and write operations. Also, low power specifications and high performance specifications of the nonvolatile memory have been demanded increasingly. For example, techniques for reading a large amount of data from nonvolatile memories are important in the field of artificial intelligence (AI). To satisfy such a requirement, optimizing operations of a nonvolatile memory is needed.

In a memory operation of a nonvolatile memory system, generally, a setting up operation may be performed on various lines before actual write and read operations, etc., and a recovery period may be executed as an initialization operation on various lines after the write and read operations, etc. However, a setting up period or the recovery period may not only increase a period for the whole memory operation, but may also increase power consumption.

### SUMMARY

The present disclosure relates to an electronic device, and more particularly, to a nonvolatile memory device for selectively skipping part of a read operation according to a timing of a read command, an operating method of the nonvolatile memory device, and a storage device including the nonvolatile memory device.

The present disclosure provides a nonvolatile memory device for selectively skipping part of a read operation according to a timing of a read command, in order to reduce a period of a memory operation to improve read performance as well as to reduce power consumption, an operating method of the nonvolatile memory device, and a storage device including the nonvolatile memory device.

According to an aspect of the present disclosure, an operating method of a nonvolatile memory device includes performing, based on a first read command, on a first selected word line, a first sensing operation that starts by a first read order, the first read order indicating an order of applying at least two first read voltages, based on receiving a second read command before the first sensing operation is finished, finishing the first sensing operation without performing a first recovery operation, and performing, based on the second read command, on a second selected word line, a second sensing operation that starts by a second read order, the second read order being based on a first address of the first read command and a second address of the second read command.

According to another aspect of the present disclosure, a nonvolatile memory device includes a memory cell array comprising a plurality of memory blocks each connected to a plurality of string select lines, a plurality of word lines, and a plurality of bit lines, a voltage generator configured to provide a voltage to word lines that are connected to a selected memory block of the plurality of memory blocks, a row decoder configured to select a string select line of the plurality of string select lines that is connected to the selected memory block and a word line of the word lines that is connected to the selected memory block, and, a control logic circuit configured to perform a read operation by controlling, based on a read command, the voltage generator and the row decoder. The control logic circuit is configured to perform, based on a first read command, a first setting up operation on a first selected string select line of the plurality of string select lines and the word lines, perform, on a first selected word line of the word lines, a first sensing operation that starts by a first read order, the first read order corresponding to an order of applying at least two read voltages, and perform, based on a second read command after the first read command and on a second selected word line of the word lines, a second sensing operation that starts by a second read order, the second read order being based on a first address of the first read command and a second address of the second read command.

According to another aspect of the present disclosure, a storage device includes a plurality of nonvolatile memories each comprising a plurality of string select lines and a plurality of word lines, a memory controller configured to send a plurality of read commands to the plurality of nonvolatile memories in response to read requests by a host, two or more nonvolatile memories of the plurality of nonvolatile memories are configured to start, based on a first read command and at different time points, first setting up operations that are performed on a first selected string select line of the plurality of string select lines, and the plurality of word lines, perform, on a first selected word line of the plurality of word lines, a first sensing operation that starts by a first read order, based on receiving a second read command subsequent to the first read command before the first sensing operation is finished, finish the first sensing operation without a first recovery operation on the first selected word line, perform, on a second selected word line of the plurality of word lines, a second sensing operation that starts by a second read order, the second read order being based on a first address of the first read command and a second address of the second read command.

### BRIEF DESCRIPTION OF THE DRAWINGS

Implementations will be more clearly understood from the following detailed description taken in conjunction with the accompanying drawings in which:

FIG. 1 is a block diagram of a storage system according to implementations;

FIG. 2 is a block diagram of a nonvolatile memory device according to implementations;

FIGS. 3 and 4 are perspective views of a memory block according to implementations;

FIG. 5 is a circuit diagram of a memory block according to an implementation;

FIGS. 6 and 7 are diagrams for describing an example of a memory block including at least two pages;

FIGS. 8 and 9 are timing diagrams of voltages for performing a read operation according to implementations;

FIG. 10 is a flowchart of an operating method of a nonvolatile memory device, according to implementations;

FIG. 11 is an example timing diagram of voltages for performing read operations on the same string select lines and the same word lines;

FIG. 12 is an example timing diagram of voltages for performing read operations on different string select lines and the same word lines;

FIG. 13 is an enlarged diagram of a second recovery and a setting up operation of FIG. 12;

FIG. 14 is an example timing diagram of voltages for performing read operations on the same string select lines and different word lines;

FIG. 15 is an example timing diagram of voltages for performing read operations on different string select lines and different word lines;

FIG. 16 is an example timing diagram of voltages for performing sequential read operations;

FIG. 17 is a diagram for describing an example of a read order of a sequential read operation according to a type of a memory cell;

FIG. 18 is a block diagram of a storage device according to implementations;

FIG. 19 is an example graph of a current generated in a read operation performed by one nonvolatile memory according to a comparative implementation;

FIG. 20 is an example graph of a total current generated in read operations performed by two or more nonvolatile memories according to a comparative implementation;

FIG. 21 is a diagram for describing an example of an operation of managing a timing at which a peak current is generated in a read operation, according to a comparative implementation;

FIG. 22 is an example graph of a current generated in a read operation according to implementations; and

FIG. 23 is a diagram for describing an example of an operation of managing a timing at which a peak current is generated in a read operation, according to an implementation.

### DETAILED DESCRIPTION

Hereinafter, an implementation will be described in detail with reference to the accompanying drawings.

The expressions “first,” “second,” etc. used in this specification may modify various components, regardless of the order and/or importance, and may be used only to distinguish one component from another and may not define the components. For example, a first user device and a second user device may indicate different user devices, regardless of the order or importance. For example, without deviating from the scope of the claims described in the present specification, a first component may be referred to as a second component, and similarly, the second component may be referred to as the first component.

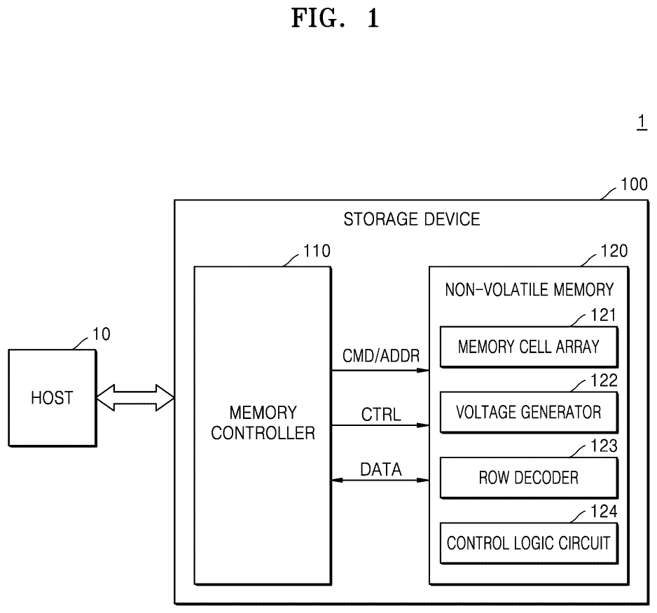

FIG. 1 is a block diagram of a storage system 1 according to implementations.

Referring to FIG. 1, the storage system 1 may include a host 10 and a storage device 100.

The host 10 may communicate with the storage device 100 through an interface (for example, nonvolatile memory express (NVMe), NVMe management interface (MI), or NVMe over fabric (NVMeof)). The host 10 may provide a write request, a logic address, and data to the storage device 100. The host 10 may provide a read quest and a logic address to the storage device 100.

According to implementations, the read request may include a sequential read request for requesting a sequential read operation and/or a random read request for requesting a random read operation.

The storage device 100 may include a memory controller 110 and a nonvolatile memory 120. The memory controller 110 and the nonvolatile memory 120 may be integrated into one semiconductor device.

The memory controller 110 may control the nonvolatile memory 120 to read data DATA stored in the nonvolatile memory 120 or write (or program) the data DATA in the nonvolatile memory 120, in response to the request (for example, the write request or the read request) provided from the host 10. In detail, the memory controller 110 may control a write operation (or a program operation), a read operation, and an erase operation of the nonvolatile memory 120 by providing a command CMD/address ADDR and/or a control signal CTRL to the nonvolatile memory 120. Also, the data DATA to be written or the data DATA to be read may be transmitted and received between the memory controller 110 and the nonvolatile memory 120. The command CMD/address ADDR according to the present disclosure may be briefly referred to as a command.

According to implementations, a read operation may include a sequential read operation or a random read operation. The sequential read operation may refer to an operation of sequentially reading data stored in consecutive storage areas (for example, memory cells corresponding to consecutive pages, etc.). A sequential read command for instructing the sequential read operation may include consecutive addresses. The random read operation may refer to an operation of reading data stored in a random storage area. A random read command for instructing the random read operation may include at least one address.

According to implementations, the memory controller 110 may provide at least one read command to the nonvolatile memory 120. The read command may include an address (for example, a physical address). The address may include a block address, a row address, and a column address.

Based on a command of the memory controller 110, the nonvolatile memory 120 may perform an operation according to the command. For example, based on a read command, the nonvolatile memory 120 may perform a read operation.

According to implementations, the nonvolatile memory 120 may include a memory cell array 121, a voltage generator 122, a row decoder 123, and a control logic circuit 124.

The memory cell array 121 may include a plurality of memory blocks. Each of the plurality of memory blocks may be connected to a plurality of string select lines, a plurality of word lines, and a plurality of bit lines. Each memory block may include a plurality of memory cells.

The voltage generator 122 may generate various voltages for performing operations according to commands. According to implementations, the voltage generator 122 may generate various voltages to be applied to word lines and string select lines connected to a memory block selected from among the plurality of memory blocks.

The row decoder 123 may select one string select line from among the string select lines connected to the selected memory block and may select one word line from among the word lines connected to the selected memory block.

The control logic circuit 124 may control the voltage generator 122 and the row decoder 123 to perform an operation according to a command.

According to implementations, the control logic circuit 124 may perform a read operation by controlling the voltage generator 122 and the row decoder 123 based on a read command. For example, the control logic circuit 124 may output, to the voltage generator 122 and the row decoder 123, based on the read command (and an address), at least one control signal for performing the read operation. According to implementations, the read operation may include a setting up operation, a sensing operation, and a recovery operation. According to some implementations, when a plurality of read operations are sequentially performed, some of the plurality of read operations may omit (or skip) the setting up operation and/or the recovery operation. The sensing operation may include a pre-charge operation and a develop operation.

According to implementations, the control logic circuit 124 may perform, based on a first read command, a first setting up operation on a first selected string select line, and the word lines connected to the selected memory block. The control logic circuit 124 may perform a first sensing operation starting as a first read order, on a first selected word line. The control logic circuit 124 may omit a first recovery operation and finish the first sensing operation on the first selected word line, based on a reception timing of the second read command (e.g., whether or not a second read command is received before the first sensing operation is finished). The control logic circuit 124 may perform, based on a second read command, a second sensing operation on a second selected word line, the second sensing operation starting as a second read order varying depending on a first address of the first read command and a second address of the second read command. The read order may refer to an order for reading states (for example, an erase state and at least one program state) corresponding to a certain threshold voltage distribution of a memory cell.

As described above, by omitting the recovery operation and/or the setting up operation and/or adaptively changing the read order to reduce the shifting amount of the read voltage, a time period for the read operation may be reduced, latency of the memory operation may be reduced, and power consumption may be reduced.

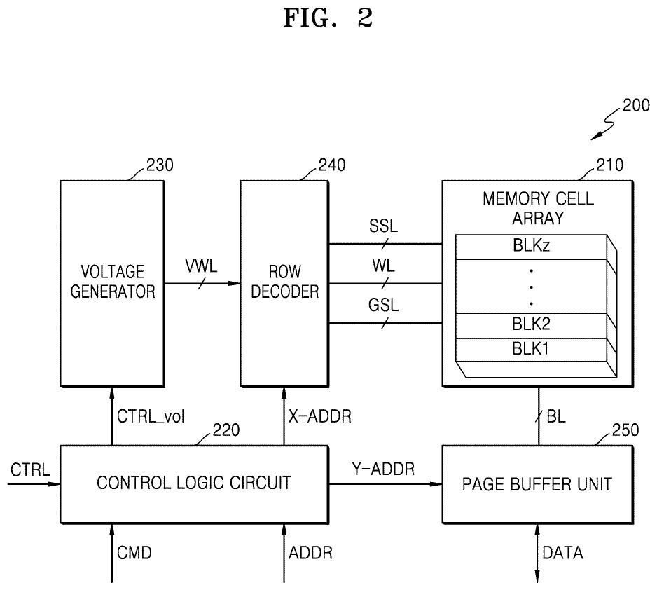

FIG. 2 is a block diagram of a nonvolatile memory device 200 according to implementations.

Referring to FIG. 2, the nonvolatile memory device 200 may correspond to the nonvolatile memory 120 of FIG. 1. The nonvolatile memory device 200 may include a memory cell array 210, a control logic circuit 220, a voltage generator 230, a row decoder 240, and a page buffer 250. According to an implementation, the nonvolatile memory device 200 may further include a data input and output circuit or an input and output interface.

The memory cell array 210 may be connected to a plurality of word lines WL, a plurality of string select lines SSL, a plurality of ground select lines GSL, and a plurality of bit lines BL. The memory cell array 210 may be connected to the row decoder 240 through the plurality of word lines WL, the plurality of string select lines SSL, and the plurality of ground select lines GSL and may be connected to the page buffer 250 through the plurality of bit lines BL.

The memory cell array 210 may include a plurality of memory blocks BLK1 to BLKz. For example, each of the plurality of memory blocks BLK1 to BLKz may have a three-dimensional (3D) structure (or a vertical structure). The plurality of memory blocks BLK1 to BLKz may be selected by the row decoder 240. For example, the row decoder 240 may select a memory block corresponding to a block address from among the plurality of memory blocks BLK1 to BLKz.

Each of memory cells included in the plurality of memory blocks BLK1 to BLKz may store at least one or more bits. For example, the memory cell may include a single level cell (SLC), a multi-level cell (MLC), a triple-level cell (TLC), or a quad-level cell (or a quadruple-level cell) (QLC). However, the present disclosure is not limited to the examples described above, and the memory cell may store data of 5 bits or more. The plurality of memory blocks BLK1 to BLKz may include at least one of an SLC block including SLCs, an MLC block including MLCs, a TLC block including TLCs, and a QLC block including QLCs. The plurality of memory blocks BLK1 to BLKz may be realized as a combination of the blocks described above. For example, some of the plurality of memory blocks BLK1 to BLKz may include SLC blocks, and the others may include MLC blocks or TLC blocks.

When an erase voltage is applied to the memory cell array 210, the memory cells may become erased, and when a program voltage is applied to the memory cell array 210, the memory cells may become programmed. Here, each memory cell may have an erase state or at least one program state. The number of program states may be determined according to a memory cell type (for example, an SLC, an MLC, a TLC, a QLC, etc.).

The control logic circuit 220 may generally control various operations in the nonvolatile memory device 200. For example, the control logic circuit 220 may output, based on a command CMD, an address ADDR, and a control signal CTRL, various control signals to write data to the memory cell array 210 or read data from the memory cell array 210. Various control signals output by the control logic circuit 220 may be provided to the voltage generator 230, the row decoder 240, and the page buffer 250. The control logic circuit 220 may provide a voltage control signal CTRL_vol to the voltage generator 230. The control logic circuit 220 may provide a row address X-ADDR to the row decoder 240. The control logic circuit 220 may provide a column address Y-ADDR to the page buffer 250.

The control logic circuit 220 may perform the operation of the control logic circuit 124 described above with reference to FIG. 1.

The voltage generator 230 may generate, based on the voltage control signal CTRL_vol, various types of word line voltages VWL for performing a program operation, a read operation, and an erase operation on the memory cell array 210. For example, the voltage generator 230 may generate a program voltage, a read voltage, an erase voltage, a pass voltage (for example, a program pass voltage, a read pass voltage, a verify pass voltage, etc.), an erase allowable voltage, a verify voltage (for example, a program verify voltage or an erase verify voltage), etc. The plurality of word line voltages VWL may be provided to the plurality of word lines WL. For example, the program voltage, the verify voltage, the read voltage, or the like may be provided to a word line selected from among the plurality of word lines WL, and the pass voltage may be provided to word lines non-selected from among the plurality of word lines WL. The selected word line may refer to at least one word line selected by a row address X-ADDR.

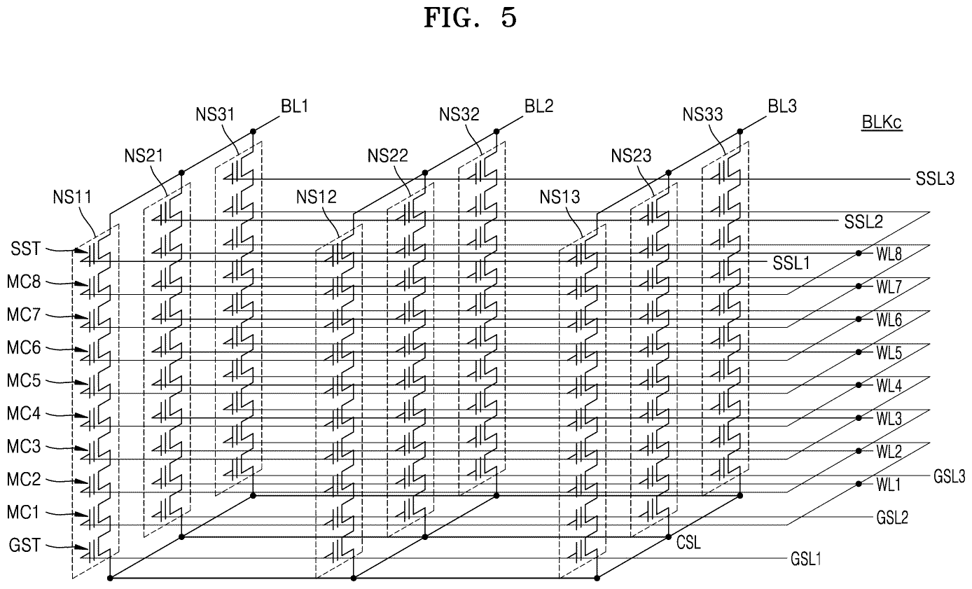

During an erase operation, the voltage generator 230 may apply an erase voltage to a well and/or a common source line (for example, a common source line CSL of FIG. 5) of a memory block. Also, the voltage generator 230 may apply, based on an erase address, an erase allowable voltage (for example, a ground voltage) to all of the word lines of the memory block or some word lines included in some sub-blocks. During an erase verify operation, the voltage generator 230 may apply an erase verify voltage to all of the word lines WL of one memory block or may apply an erase verify voltage in word line units.

During a program operation, the voltage generator 230 may generate a program voltage to be applied to a word line selected from among the plurality of word lines WL and may generate a program pass voltage to be applied to word lines non-selected from among the plurality of word lines WL. Also, during a program verify operation, the voltage generator 230 may generate a program verify voltage to be applied to the selected word line and may generate a verify pass voltage to be applied to the non-selected word lines.

During a read operation, the voltage generator 230 may generate at least one read voltage to be applied to a word line selected from among the plurality of word lines WL and may generate a read pass voltage to be applied to non-selected word lines. According to implementations, when a memory cell type is an MLC or more, at least two read voltages may be sequentially applied to a selected word line according to a read order, when a sensing operation of a read operation is performed.

The row decoder 240 may select a certain word line from among the word lines WL, in response to a row address X-ADDR. For example, during a read operation, the row decoder 240 may transmit a read voltage to the word line selected according to the row address X-ADDR and transmit a read pass voltage to non-selected word lines. The row decoder 240 may select some string select lines from among the string select lines SSL and some ground select lines from among the ground select lines GSL in response to the row address X-ARRD.

The page buffer 250 may select at least some bit lines from among the plurality of bit lines BL in response to a column address Y-ADDR. During a verify operation (for example, an erase verify operation or a program verify operation) or the read operation, the page buffer 250 may operate as a sense amplifier and may sense data stored in a selected memory cell through the selected bit line. Also, during a program operation, the page buffer 250 may operate as a write driver and may input data to be stored in the memory cell array 210. The page buffer 250 may store data read from the memory cell array 210 or store data to be stored in the memory cell array 210.

The page buffer 250 may include a plurality of page buffer circuits connected to the plurality of bit lines BL, respectively. The plurality of page buffer circuits may be arranged to correspond to the bit lines, respectively, and each page buffer circuit may include a plurality of latches.

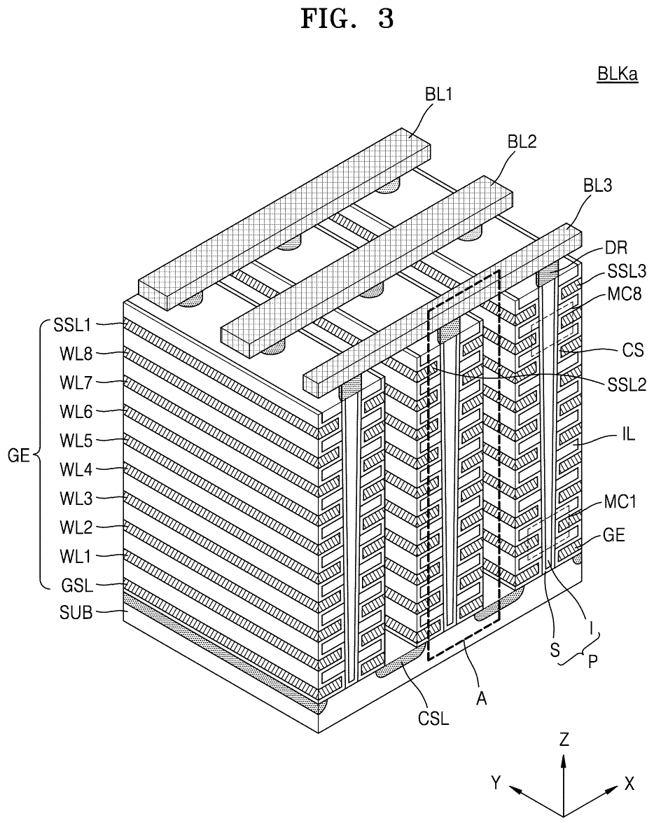

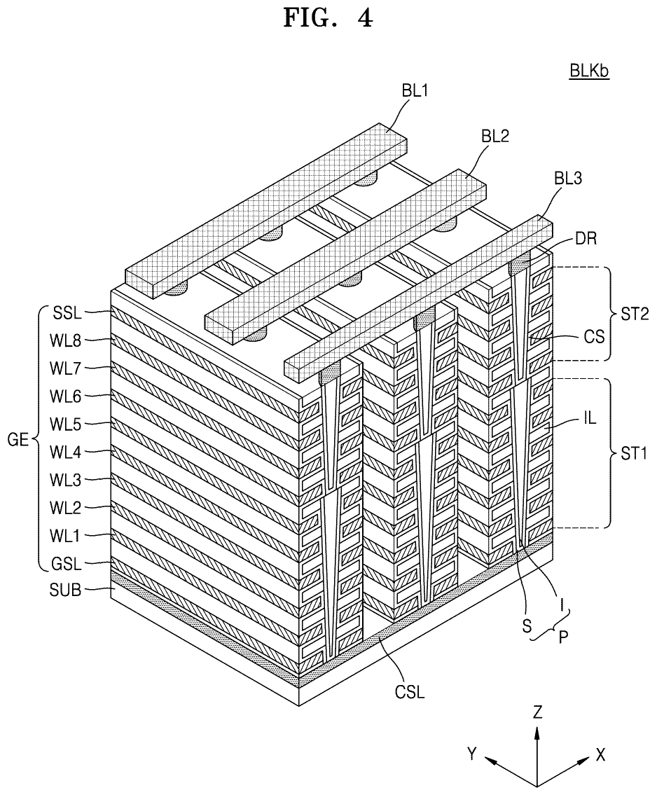

FIGS. 3 and 4 are perspective views of a memory block according to implementations. In detail, FIG. 3 is a perspective view of a memory block BLKa according to an implementation, and FIG. 4 is a perspective view of a memory block BLKb according to an implementation.

Referring to FIG. 3, a common source line CSL extending in a Y direction may be provided on a substrate SUB. A plurality of insulating layers IL may extend in the Y direction and may be sequentially provided in a Z direction on an area of the substrate SUB between adjacent common source lines CSL. A plurality of pillars P may be provided to pass through the plurality of insulating layers IL in the Z direction and to be in contact with the substrate SUB. A surface layer S of the plurality of pillars P may function as a channel area, and an internal layer I of the plurality of pillars P may include an insulating material or an air gap. A charge storage layer CS may be provided in an area between adjacent common source lines CSL, a gate electrode GE may be provided on an exposed surface of the charge storage layer CS, and drain contacts DR may be provided on the plurality of pillars P. Bit lines BL1 to BL3 may be provided to extend in an X direction and to be apart from each other by a certain distance in the Y direction. The number of lines GSL, SSL1 to SSL3, and WL1 to WL8, the number of memory cells MC1 to MC8, and the number of bit lines BL1 to BL3, included in the memory block BLKa, are examples, and may be greater or less than these examples, according to an implementation.

Referring to FIG. 4, descriptions about the memory block BLKb, which are the same as described with reference to FIG. 3, are omitted. A first memory stack ST1 may be provided on the substrate SUB. The memory block BLKb may further include, on the first memory stack ST1 generated as described above, a second memory stack ST2 generated by the same method as the first memory stack ST1.

FIG. 5 is a circuit diagram of a memory block BLKc according to an implementation.

Referring to FIG. 5, the memory block BLKc may include a plurality of NAND strings NS11 to NS33, a plurality of word lines, namely, first to eighth word lines WL1 to WL8, a plurality of bit lines, namely, first to third bit lines BL1 to BL3, ground select lines, namely, first to third ground select lines GSL1 to GSL3, a plurality of string select lines, namely, first to third string select lines SSL1 to SSL3, and a common source line CSL. Here, the number of NAND strings and the number of various lines are examples and may be greater or less than the examples, according to an implementation.

Each NAND string (for example, the NAND string NS11) may include a string select transistor SST, a plurality of memory cells, namely, first to eighth memory ells MC1 to MC8, and a ground select transistor GST which are connected in series. Hereinafter, for convenience, a NAND string is referred to as a string.

The strings commonly connected to one bit line may form one column. For example, the strings NS11, NS21, and NS31 commonly connected to the first bit line BL1 may correspond to a first column, the strings NS12, NS22, and NS32 commonly connected to the second bit line BL2 may correspond to a second column, and the strings NS13, NS23, and NS33 commonly connected to the third bit line BL3 may correspond to a third column.

The strings connected to one string select line may form one row. For example, the strings NS11, NS12 and NS13 commonly connected to the first string select line SSL1 may correspond to a first row, the strings NS21, NS22, and NS23 commonly connected to the second string select line SSL2 may correspond to a second row, and the strings NS31, NS32, and NS33 commonly connected to the third string select line SSL3 may correspond to a third row.

A corresponding string select transistor SST may be connected to a corresponding string select line from among the first to third string select lines SSL1 to SSL3. The plurality of memory cells, namely, the first to eighth memory cells MC1 to MC8, may be connected to the corresponding first to eighth word lines WL1 to WL8, respectively. A corresponding ground select transistor GST may be connected to a corresponding ground select line from among the first to third ground select lines GSL1, GSL2, and GSL3. The string select transistor SST may be connected to a corresponding bit line, and the ground select transistor GST may be connected to the common source line CSL.

The same word line (for example, the first word line WL1) may be commonly connected, and the first to third string select lines SSL1 to SSL3 may be separated from one another. For example, when memory cells connected to the first word line WL1 and included in the strings NS11, NS12, and NS13 are programmed, the first word line WL1 and the first string select line SSL1 may be selected.

In a NAND flash memory including the memory block BLKc, an erase operation may be performed in units of memory blocks and a program operation may be performed in units of at least one page included in each of the first to eighth word lines WL1 to WL8. For example, when the memory cell is an MLC, a TLC, or a QLC, a plurality of pages may correspond to each word line. For example, when the memory cell is an MLC, each word line may correspond to a least significant bit (LSB) page and a most significant bit (MSB) page. For example, when the memory cell is a TLC, each word line may correspond to an LSB page, a central significant bit (CSB) page, and an MSB page.

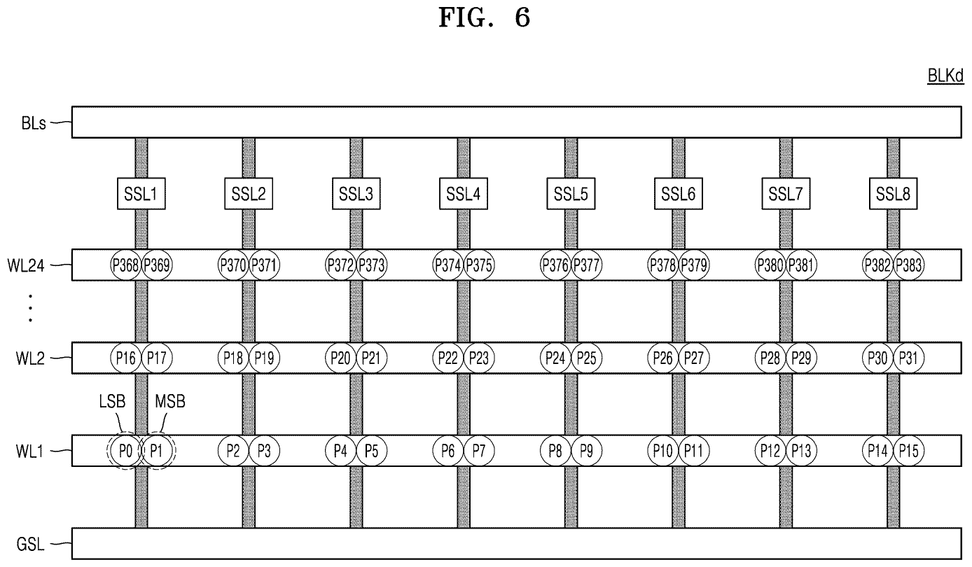

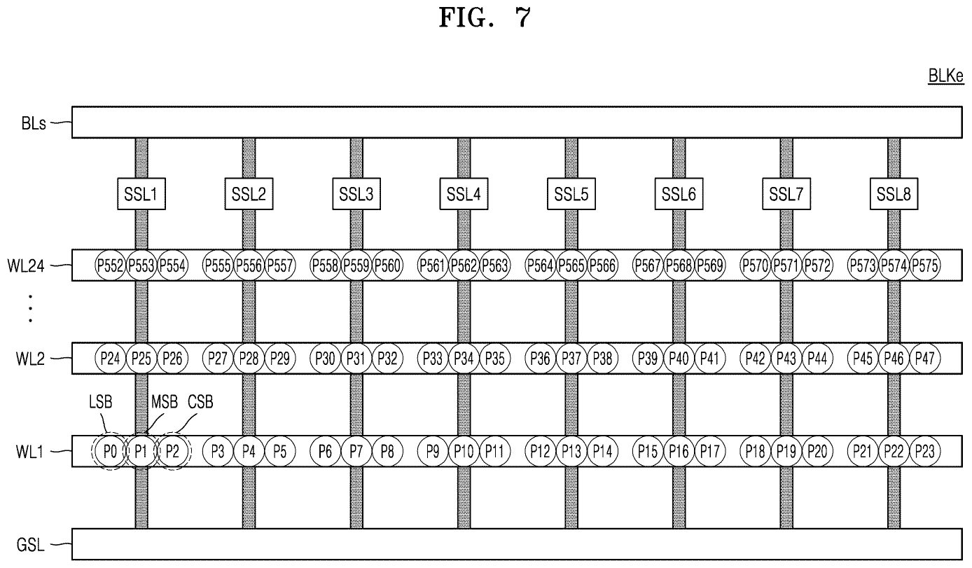

FIGS. 6 and 7 are diagrams for describing an example of a memory block including at least two pages. In detail, FIG. 6 is the diagram of an example of a memory block BLKd including MLCs, and FIG. 7 is the diagram of an example of a memory block BLKe including TLCs.

Referring to FIG. 6, the memory cells of the memory block BLKd may be arranged as a 3D structure in a vertical-NAND (VNAND) memory. The number of string select lines, namely, first to eighth string select lines SSL1 to SSL8, is illustrated as 8, but it is an example. The bit lines BLs may be connected to each of the first to eighth string select lines SSL1 to SSL8. In FIG. 6, each of a plurality of word lines, namely, first to twenty-fourth word lines WL1 to WL24, may correspond to two pages. Referring to FIG. 6, for example, a component illustrated as “Pi (i is an integer greater than or equal to 0)” in each word line may indicate one page. Any one of the two pages corresponding to each word line may indicate an LSB, and the other may indicate an MSB. For example, a page P0 of pages P0 and P1 corresponding to the first word line WL1 and the first string select line SSL1 may indicate an LSB, and the page P1 may indicate an MSB. However, the present disclosure is not limited to the example described above. As described above, in the plurality of string select lines, namely, the first to eighth string select lines SSL1 to SSL8, the memory cells connected to each word line may store data corresponding to 16 pages (for example, first to sixteenth pages P0 to P15). Likewise, the memory cells connected to each of the second to twenty-fourth word lines WL2 to WL 24 may store data corresponding to 16 pages.

By a selection operation with respect to the plurality of string select lines, namely, the first to eighth string select lines SSL1 to SSL8, and the plurality of word lines, namely, the first to twenty-fourth word lines WL1 to WL24, any one page may be selected. For example, when any one string select line is selected from among the plurality of string select lines, namely, the first to eighth string select lines SSL1 to SSL8, a plurality of cell strings connected to the selected string select line may be selected. Also, when any one word line is selected from among the plurality of word lines, namely, the first to twenty-fourth word lines WL1 to WL24, a plurality of memory cells arranged at the same height in the selected plurality of cell strings may be selected. The selected memory cells may form one page.

When a sequential read operation according to an implementation is performed, the nonvolatile memory device 200 may sequentially read data stored in each page, from a certain page to a next page thereto (for example, a page illustrated with an increased number). For example, when a sequential read operation is performed from the thirteenth page P12 to an eighteenth page P17, the first word line WL1 and the seventh string select line SSL7 may be selected to sequentially read data of the thirteenth and fourteenth pages P12 and P13, the first word line WL1 and the eighth string select line SSL8 may be selected to sequentially read data of the fifteenth and sixteenth pages P14 and P15, and the second word line WL2 and the first string select line SSL1 may be selected to sequentially read data of the seventeenth and eighteenth pages P16 and P17.

Referring to FIG. 7, descriptions about the memory block BLKd, which are the same as described with reference to FIG. 6, are omitted. In FIG. 7, each of the first to twenty-fourth word lines WL1 to WL24 included in the memory block BLKe may correspond to an LSB page, an MSB page, and a CSB page. For example, the page P0 corresponding to the first word line WL1 and the first string select line SSL1 may be an LSB page, the page P1 may be an MSB page, and the page P2 may be a CSB page. However, the present disclosure is not limited to the example described above. As described above, in the first to eighth string select lines SSL1 to SSL8, the memory cells connected to the first to twenty-fourth word lines WL1 to WL24, respectively, may store data corresponding to 24 pages.

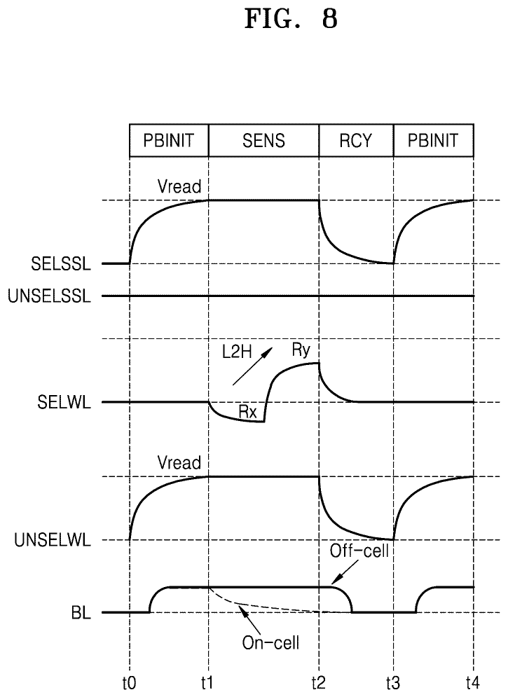

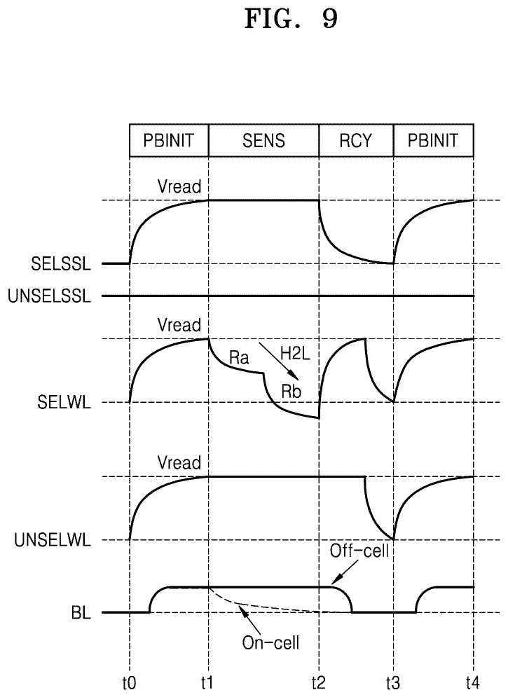

FIGS. 8 and 9 are timing diagrams of voltages for performing a read operation according to implementations. Each of FIGS. 8 and 9 is an example timing diagram of voltages for performing a read operation in response to one read command. The read operation illustrated in FIGS. 8 and 9 may include a setting up operation PBINIT, a sensing operation SENS, and a recovery operation RCY.

Referring to FIG. 8, the setting up operation PBINIT may start at a time point t0. When the setting up operation PBINIT is started, a voltage level of each of a selected string select line SELSSL and a non-selected word line UNSELWL may increase. According to implementations, while the setting up operation PBINIT is being performed, the voltage level of the selected string select line SELSSL and the voltage level of the non-selected word line UNSELWL may increase up to a level of a read pass voltage Vread. However, the present disclosure is not limited to the example described above. A selected word line SELWL may maintain a certain voltage level lower than the level of the read pass voltage Vread. The voltages that are applied to the string select lines and/or the word lines during the setting up operation may be referred to as set up voltages in the present disclosure. The voltage level may also be referred to as a voltage value in the present disclosure.

At a time point t1, the setting up operation PBINIT may be finished, and the sensing start SENS may be started. When the sensing operation SENS is started, the voltage level of the selected string select line SELSSL and the voltage level of the non-selected word line UNSELWL may be maintained as the level of the read pass voltage Vread. According to implementations, at least two read voltages may be sequentially applied to the selected word line SELWL according to a read order.

According to an implementation, the read order may be determined according to a level of a voltage applied to the selected word line SELWL in the setting up operation PBINIT finished before the sensing operation SENS is started. Referring to FIG. 8, for example, it is assumed that a memory cell may store data that is 2 bits or more. When the voltage level of the selected word line SELWL is a second voltage level lower than the level of the read pass voltage Vread when the setting up operation PBINIT is finished, first, a read voltage Rx may be applied to the selected word line SELWL, and then, a read voltage Ry having a level relatively higher than a level of the read voltage Rx may be applied to the selected word line SELWL. The read order in which a read voltage (for example, Rx) having a relatively lower level is first applied to the word line, and then, a read voltage (for example, Ry) having a relatively higher level is applied to the word line, may be referred to as an ascending order L2H. That is, the ascending order L2H may be a read order in which a read operation is sequentially performed from a threshold voltage distribution of the memory cell corresponding to a relatively lower state to a threshold voltage distribution of the memory cell corresponding to a relatively higher state.

At a time point t2, the sensing operation SENS may be finished, and the recovery operation RCY may be started. When the recovery operation RCY is started, the voltage level of each of the selected string select line SELSSL, the selected word line SELWL, and the non-selected word line UNSELWL may decrease.

Also, while the read operation is being performed, the non-selected string select line UNSELSSL may maintain the voltage level of the selected string select line SELSSL at a time point previous to the time point t0. A voltage level of at least some bit lines BL may increase to a pre-charge level during the setting up operation PBINIT. Also, according to data stored in the memory cell during a period (from the time point t1 to the time point t2) of the sensing operation SENS, the voltage level of at least some bit lines BL may decrease from the pre-charge level or may be maintained as the pre-charge level. For example, in the case of an on-cell, the voltage level of at least some bit lines BL may gradually decrease to a level equal to or less than the pre-charge level. In the case of an off-cell, the voltage level of at least some bit lines BL may be maintained as the pre-charge level. The data may be sensed in a state in which the voltage level of at least some bit lines BL is developed, and the sensed data may be stored in the page buffer 250. When an additional read command is received, the setting up operation PBINIT may be performed.

Referring to FIG. 9, descriptions about the voltage levels of the same lines (for example, SELSSL, UNSELSSL, SELWL, UNSELWL, and BL) as FIG. 8 are omitted.

While the setting up operation PBINIT is being performed, the voltage level of the selected word line SELWL may increase to the level of the read pass voltage Vread.

When the setting up operation PBINIT is finished and the sensing operation SENS is performed, at least two read voltages may be sequentially applied to the selected word line SELWL according to a read order, according to implementations. Referring to FIG. 9, for example, it is assumed that a memory cell may store data that is 2 bits or more. When the voltage level of the selected word line SELWL is a first voltage level (for example, the level of the read pass voltage Vread) higher than the second voltage level when the setting up operation PBINIT is finished, first, a read voltage Ra may be applied to the selected word line SELWL, and then, a read voltage Rb having a level relatively lower than a level of the read voltage Ra may be applied to the selected word line SELWL. The read order in which a read voltage (for example, Ra) having a relatively higher level is first applied to the word line, and then, a read voltage (for example, Rb) having a relatively lower level is applied to the word line, may be referred to as a descending order H2L. That is, the descending order H2L may be a read order in which a read operation is sequentially performed from a threshold voltage distribution of the memory cell corresponding to a relatively higher state to a threshold voltage distribution of the memory cell corresponding to a relatively lower state.

When the sensing operation SENS is finished and the recovery operation RCY is started, the voltage level of the selected word line SELWL may increase up to the level of the read pass voltage Vread, and then, may decrease down to a certain voltage level (for example, 0V or a VDD level corresponding to a supply voltage). The voltage level of the non-selected word line UNSELWL may also decrease from a time point at which the voltage level of the selected word line SELWL decreases.

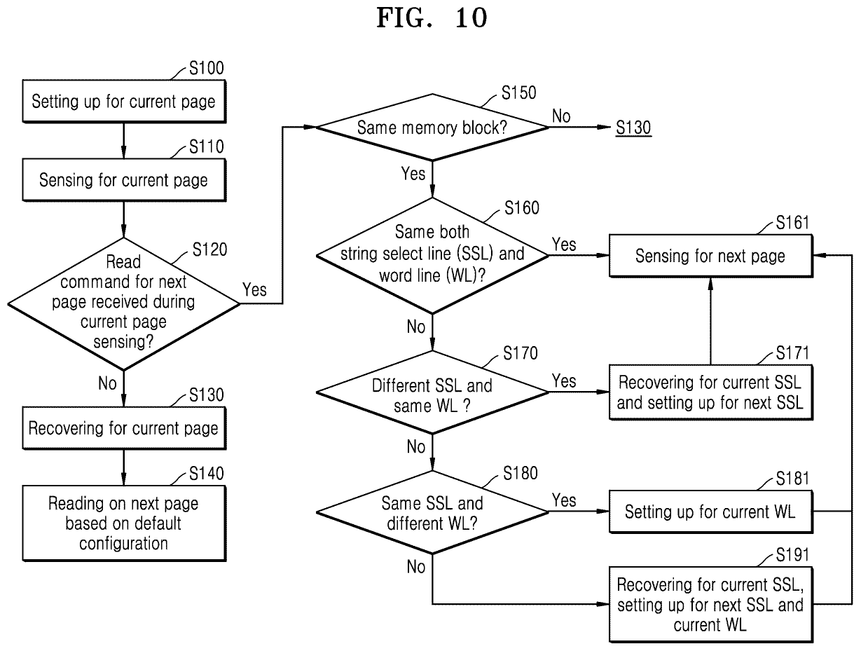

FIG. 10 is a flowchart of an operating method of the nonvolatile memory device 200, according to implementations.

Referring to FIGS. 2 and 10, in operation S100, the nonvolatile memory device 200 may perform a setting up operation on a current page, based on a first read command with respect to the current page. In operation S110, the nonvolatile memory device 200 may perform a sensing operation on the current page.

In operation S120, while the sensing operation is being performed on the current page, the nonvolatile memory device 200 may determine whether or not a second read command with respect to a next page is received.

When the second read command is received after the sensing operation (hereinafter, referred to as “a first sensing operation”) according to the first read command is finished (No in operation S120), the nonvolatile memory device 200 may perform a recovery operation on the current page in operation S130. In operation S140, after the recovery operation on the current page is finished, the nonvolatile memory device 200 may perform a read operation on the next page, based on a default configuration. In this case, the default configuration may include a read order predetermined for each memory cell. The read operation on the next page may include a setting up operation, a sensing operation, and a recovery operation. That is, the sensing operation (hereinafter, referred to as “a second sensing operation”) according to the second read command may be performed after the recovery operation according to the first read command is finished.

When the second read command is received while the first sensing operation is being performed (Yes in operation S120), the nonvolatile memory device 200 may determine, based on a first address (for example, a block address) of the first read command and a second address (for example, a block address) of the second read command, whether or not a memory block including the current page is the same as a memory block including the next page, in operation S150.

When the memory blocks are different from each other (No in operation S150), operation S130 may be performed. For example, the operations as illustrated in FIG. 8 and/or FIG. 9 may be performed.

When the memory blocks are the same as each other (Yes in operation S150), the nonvolatile memory device 200 may determine, based on a first address (for example, a row address) of the first read command and a second address (for example, a row address) of the second read command, whether or not string select lines corresponding to the current page and the next page are the same as each other and whether or not word lines corresponding to the current page and the next page are the same as each other, according to implementations.

According to an implementation, in operation S160, the nonvolatile memory device 200 may determine whether or not the string select lines are the same as each other and whether or not the word lines are the same as each other. When the string select lines are the same as each other and the word lines are the same as each other (Yes in operation S160), the nonvolatile memory device 200 may omit a recovery operation on a current word line after the sensing operation on the current page is finished and may perform the sensing operation on the next page, in operation S161.

According to an implementation, in operation S170, the nonvolatile memory device 200 may determine whether or not the string select lines are different from each other and whether or not the word lines are the same as each other. When the string select lines are different from each other and the word lines are the same as each other (Yes in operation S170), the nonvolatile memory device 200 may omit the recovery operation on the current word line and may perform a recovery operation on a current string select line and a setting up operation on a next string select line, in operation S171. Operation S161 may be performed after operation S171.

According to an implementation, in operation S180, the nonvolatile memory device 200 may determine whether or not the string select lines are the same as each other and whether or not the word lines are different from each other. When the string select lines are the same as each other and the word lines are different from each other (Yes in operation S180), the nonvolatile memory device 200 may omit the recovery operation on the current word line and may perform a setting up operation on the current word line, in operation S181. Operation S161 may be performed after operation S181.

When the conditions according to operations S160 to S180 are not satisfied (for example, No in operation S180), the nonvolatile memory device 200 may omit the recovery operation on the current word line and may perform the recovery operation on the current string select line and the setting up operation on the next string select line and the current word line, in operation S191. Operation S161 may be performed after operation S171.

According to the implementations described above, the recovery operation and/or the setting up operation may be selectively skipped, and thus, a time period to perform a read operation may be reduced and the speed of the read operation may be increased. Therefore, read performance may be improved and power consumption may be reduced.

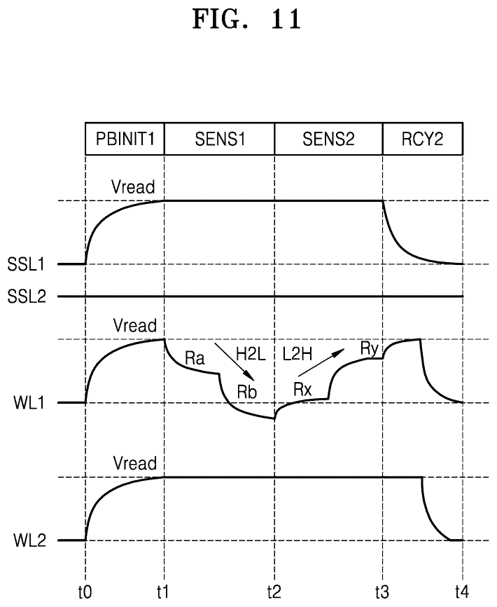

FIG. 11 is an example timing diagram of voltages for performing read operations on the same string select lines and the same word lines. An implementation of FIG. 11 is related to operations S160 and S161 of FIG. 10. For convenience of explanation, the implementation of FIG. 11 is described below based on the first and second string select lines SSL1 and SSL2 and the first and second word lines WL1 and WL2.

Referring to FIGS. 9, 10, and 11, selected string select lines and selected word lines corresponding to the first address of the first read command and the second addresses of the second read command may be the same as each other. The first read command may be a command provided before the second read command, and the second read command may be provided before a first sensing operation SENS1 is finished. In this case, according to an implementation, performing of a second sensing operation SENS2 may include determining a direction different from a first read order as a second read order, sequentially applying at least two read voltages to a second word line according to the second read order, and detecting, through a plurality of bit lines, sensing values according to the at least two read voltages. According to an implementation, the control logic circuit 220 may determine the second read order as a different direction from the first read order of the first sensing operation SENS1 and may perform the second sensing operation SENS2 according to the second read order.

The selected lines according to the present disclosure may be determined as arbitrary lines. A first selected string select line and a first selected word line may be the lines selected according to the first read command, and a second selected string select line and a second selected word line may be the lines selected according to the second read command. Hereinafter, in FIGS. 11 to 15, it is assumed that the first selected string select line corresponds to the first string select line SSL1, the second selected string select line corresponds to the second string select line SSL2, the first selected word line corresponds to the first word line WL1, and the second selected word line corresponds to the second word line WL2.

Referring to FIG. 11, for example, while a first setting up operation PBINITI and the first sensing operation SENS1 are being performed, a voltage level of the first string select line SSL1 may increase or may be maintained as the voltage level of the selected string select line SELSSL of FIG. 9. A voltage level of the second string select line SSL2 may be maintained as a certain voltage level (for example, 0V, VDD, etc.) as the non-selected string select line UNSELSSL of FIG. 9. A voltage level of the first word line WL1 may be changed as the selected word line SELWL of FIG. 9. In this case, a first read direction of the first sensing operation SENS1 may be the descending order H2L. A voltage level of the second word line WL2 may increase, may be maintained, and may decease as the non-selected word line UNSELWL of FIG. 9. At a time point t2, the first sensing operation SENS1 may be finished and a second sensing operation SENS2 may be started. The voltage levels of the first and second string select lines SSL1 and SSL2 and the voltage level of the second word line WL2 may be maintained as the voltage levels during a period from a time point t1 to the time point t2 during which the first sensing operation SENS1 is performed.

While the second sensing operation SENS2 is being performed, at least two read voltages Rx and Ry may be sequentially applied to the first word line WL1 according to the second read order. In this case, because the first read order of the first sensing operation SENS1 is the descending order H2L, the second read order may be the ascending order L2H. A level of the read voltage Rx may be lower than a level of the read voltage Ry.

When another read command is not provided after the second read command, a second recovery operation RCY2 may be performed. The voltage levels of the first and second string select lines SSL1 and SSL2 and the voltage level of the second word line WL2 may decrease like the voltage level changing during the recovery operation RCY described with reference to FIG. 9. The voltage level of the first word line WL1 may increase up to the level of the read pass voltage Vread, and then, may decrease down to a certain voltage level (for example, 0V, VDD, etc.).

According to the implementation illustrated in FIG. 11, the voltage level of the first selected word line (for example, the first word line WL1) may increase up to the level of the read pass voltage Vread during the first setting up operation PBINIT1. However, the present disclosure is not limited to the implementation illustrated in FIG. 11. According to another implementation, during the first setting up operation PBINIT1, the voltage level of the first selected word line (for example, the first word line WL1) may be pre-charged to the voltage level (for example, 0V, VDD, etc.) lower than the level of the read pass voltage Vread as illustrated in FIG. 8. In this case, the first read order in the first sensing operation SENS1 may be the ascending order L2H, and the second read order in the second sensing operation SENS2 may be the descending order H2L.

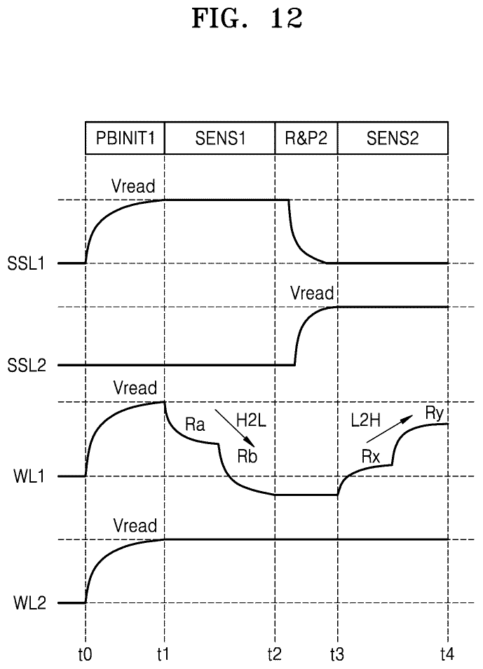

FIG. 12 is an example timing diagram of voltages for performing read operations on different string select lines and the same word lines. An implementation of FIG. 12 is related to operations S170 and S171 of FIG. 10. For convenience of explanation, the implementation of FIG. 12 is described below based on the first and second string select lines SSL1 and SSL2 and the first and second word lines WL1 and WL2.

Referring to FIGS. 9, 10, and 12, the first and second selected string select lines respectively corresponding to the first and second addresses may be different from each other, and the first and second selected word lines respectively corresponding to the first and second addresses may be the same as each other. In this case, according to an implementation, after the first sensing operation SENS1 is finished, a recovery operation may be performed on the first selected string select line, and after the recovery operation is started on the first selected string select line, a setting up operation may be performed on the second selected string select line. Also, performing of a second sensing operation SENS2 may include, after the setting up operation on the second selected string select line is finished, determining a different direction from a first read order as a second read order, sequentially applying at least two read voltages to the second selected word line according to the second read order, and detecting, through a plurality of bit lines, sensing values according to the at least two read voltages. According to an implementation, the control logic circuit 220 may perform, after the first sensing operation SENS1 is finished, a second recovery operation of recovering a first setting up level of the first selected string select line as a second setting up level, may perform a second setting up operation of pre-charging the second selected string select line as the first setting up level, and may perform, after the second setting up operation is finished, the second sensing operation SENS2 by having the different direction from the first read order as the second read order.

Referring to FIG. 12, for example, descriptions about the same lines (for example, SSL1, SSL2, WL1, and WL2) as in FIG. 11 are omitted. A second recovery and setting up operation R&P2 may be performed at a time point t2. While the second recovery and setting up operation R&P2 is being performed, a voltage level of the first string select line SSL1 may decrease and a voltage level of the second string select line SSL2 may increase, and a voltage level of the first word line WL1 may be maintained as a level of a read voltage lastly applied when the first sensing operation SEN1 is finished. As described above with reference to FIG. 11, the second sensing operation SENS2 may be performed at a time point t3, and at least two read voltages Rx and Ry may be applied to the first word line WL1 according to the second read order (for example, the ascending order L2H).

Although not shown, when another read command is not provided after a second read command, the second recovery operation RCY2 may be performed, similarly as illustrated in FIG. 11.

According to another implementation different from the implementation illustrated in FIG. 12, when, during a first setting up operation PBINIT1, a voltage level of the first selected word line (for example, the first word line WL1) is pre-charged to a voltage level lower than a level of the read pass voltage Vread, a first read order may be an ascending order L2H and a second read order may be a descending order H2L.

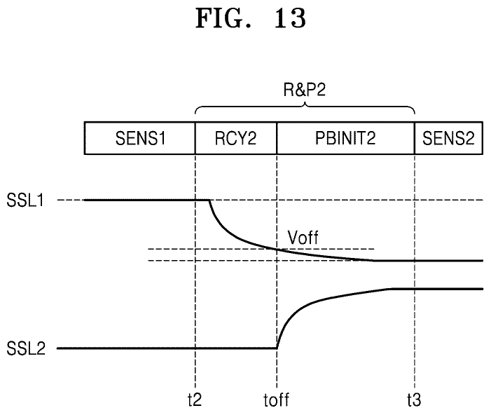

FIG. 13 is an enlarged diagram of the second recovery and setting up operation R&P2 of FIG. 12.

Referring to FIGS. 5, 12, and 13, the second recovery and setting up operation R&P2 may include a second recovery operation RCY2 and a second setting up operation PBINIT2. The second recovery operation RCY2 may be performed first, at a time point t2. While the second recovery operation RCY2 is being performed, the second setting up operation PBINIT2 may be performed from a time point toff. The time point toff may be a time period at which the voltage level of the first string select line SSL1 decreases down to a turn off level Voff due to the second recovery operation RCY2. The turn off level Voff may be a level at which the string select transistor SST connected to the first string select line SSL12 is turned off. The second setting up operation PBINIT2 may be finished at a time point t3.

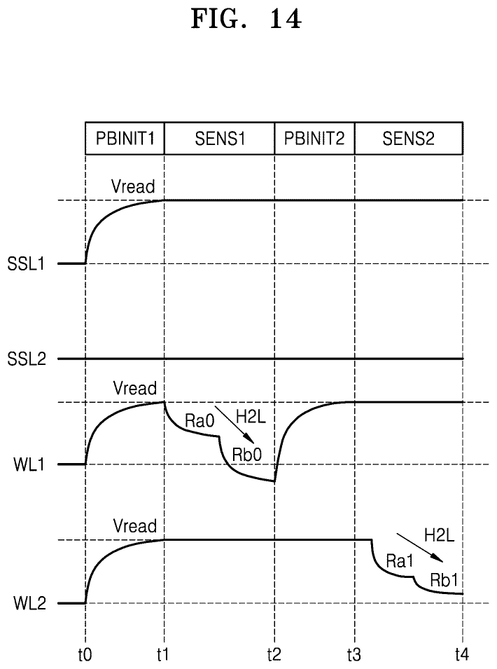

FIG. 14 is an example timing diagram of voltages for performing read operations on the same string select lines and different word lines. An implementation of FIG. 14 is related to operations S180 and S181 of FIG. 10. For convenience of explanation, the implementation of FIG. 14 is described below based on the first and second string select lines SSL1 and SSL2 and the first and second word lines WL1 and WL2.

Referring to FIGS. 9, 10, and 14, first and second selected string select lines may be the same as each other, and first and second selected word lines may be different from each other. In this case, according to an implementation, after the first sensing operation SENS1 is finished, a setting up operation may be performed on the first selected word line. The second sensing operation SENS2 may include, after the setting up operation is finished, sequentially applying at least two read voltages to the second word line according to the second read order, and detecting, through a plurality of bit lines, sensing values according to the at least two read voltages. According to an implementation, the control logic circuit 220 may perform, after the first sensing operation SENS1 is finished, the second setting up operation PBINIT2 of pre-charging the first selected word line to the first setting up level. Also, after the second setting up operation PBINIT2 is finished, the control logic circuit 220 may perform the second sensing operation SENS2.

Referring to FIG. 14, for example, descriptions about the same lines (for example, SSL1, SSL2, WL1, and WL2) as in FIG. 11 are omitted. At a time point t2, the second setting up operation PBINIT2 may be performed on the first word line WL1. While the second setting up operation PBINIT2 is being performed, a voltage level of the first word line WL1 may increase up to a level of the read pass voltage Vread.

According to an implementation, a period from the time point t2 to a time point t3, during which the second setting up operation PBINIT2 is performed, may vary according to a voltage level of a read voltage applied to the first selected word line when the first sensing operation SENS1 is finished. Referring to FIG. 14, for example, it is assumed that the first sensing operation SENS1 is finished at the time point t2. As a level of a read voltage Rb0 applied to the first word line WL1 at the time point t2 decreases, a time period for a level of a read voltage Rb0 to increase up to the level of the read pass voltage Vread may increase. Thus, the period from the time point t2 to the time point t3, during which the second setting up operation PBINIT2 is performed, may increase. Likewise, as a level of the read voltage Rb0 applied to the first word line WL1 at the time point t2 increases, the period from the time point t2 to the time point t3, during which the second setting up operation PBINIT2 is performed, may decrease. According to an implementation, a period during which a setting up operation (for example, the second setting up operation PBINIT2) is performed on a subsequently selected word line may be predetermined for each voltage level of the read voltage, and the determined values may be stored in the control logic circuit 220.

After the second setting up operation PBINIT2 is finished at the time point t3, the second sensing operation SENS2 may be performed on the second word line WL2. According to an implementation, a voltage level of the second word line WL2 may be maintained as the level of the read pass voltage Vread before the second sensing operation SENS2, and thus, the second read order in the second sensing operation SENS2 may be the descending order H2L. Although not shown, when another read command is not provided after a second read command, the second recovery operation RCY2 may be performed similarly as illustrated in FIG. 11.

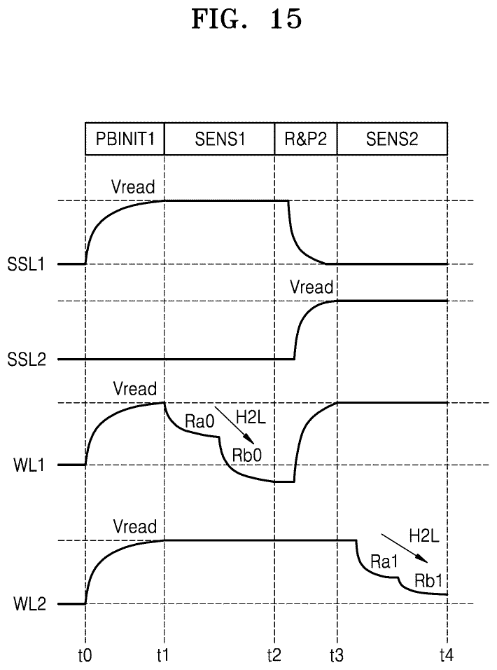

FIG. 15 is an example timing diagram of voltages for performing read operations on different string select lines and different word lines. An implementation of FIG. 15 is related to operations S180 and S181 of FIG. 10. For convenience of explanation, the implementation of FIG. 15 is described below based on the first and second string select lines SSL1 and SSL2 and the first and second word lines WL1 and WL2.

Referring to FIGS. 9, 10, and 15, first and second selected string select lines may be different from each other, and first and second selected word lines may be different from each other. In this case, according to an implementation, after the first sensing operation SENS1 is finished, a recovery operation may be performed on the first selected string select line, and after the recovery operation on the first selected string select line is started, a setting up operation may be performed on each of the second selected string select line and the first selected word line.

The second sensing operation SENS2 according to an implementation may include, after the setting up operation on the first word line and the second string select line is finished (for example, after a time point t3), sequentially applying at least two read voltages (for example, Ra1 and Rb1) to the second selected word line (for example, the second word line WL2) according to a second read order (for example, the descending order H2L), and detecting, through a plurality of bit lines, sensing values according to the at least two read voltages.

According to an implementation, the control logic circuit 220 may perform, after the first sensing operation SENS1 is finished, a second recovery operation of recovering a first setting up level of the first selected string select line as a second setting up level, may perform a second setting up operation of pre-charging the first selected word line and the second selected string select line to the first setting up level, and may perform, after the second setting up operation is finished, the second sensing operation SENS2. The second recovery operation and the second setting up operation may be included in the second recovery and setting up operation R&P2.

Referring to FIG. 15, for example, a first read operation from a time point t0 to the time point t3, the second recovery and setting up operation R&P2, and the second sensing operation SENS2 from the time point t3 to a time point t4 are the same as described above with reference to FIG. 14. Although not shown, the second recovery operation RCY2 may be performed after the time point t4.

As described above with reference to FIG. 13, a setting up operation of the second recovery and setting up operation R&P2 illustrated in FIG. 15 may be started from a time point at which a level of the voltage applied to the first string select line SSL1 becomes a turn off level. Also, a period (or a time period) from a start point to an end point of the setting up operation of the second recovery and setting up operation R&P2 may vary according to a voltage level of a read voltage Rb0 applied to the first word line WL1 when the first sensing operation SENS1 is finished.

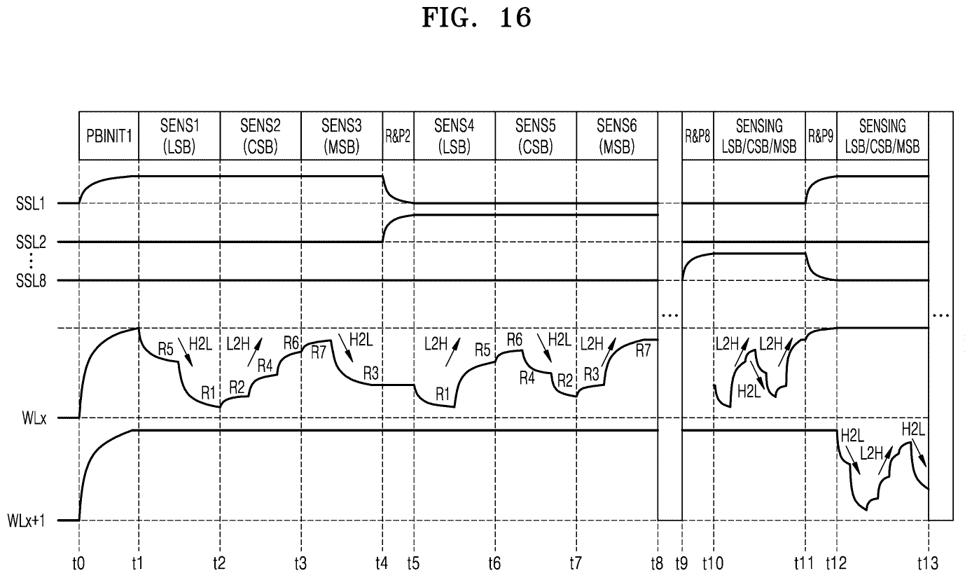

FIG. 16 is an example timing diagram of voltages for performing sequential read operations. The same descriptions about implementations of FIG. 16 as described above with reference to FIGS. 11 to 15 are omitted.

Referring to FIG. 16, read operations from a time point t0 to a time point t4 may be the read operations on the same string select lines and the same word lines described above with reference to FIG. 11.

According to an implementation, two adjacent word lines WLx and WLx+1 may be arbitrary word lines and may correspond to an LSB page, a CSB page, and an MSB page. In this case, first to third sensing operations SENS1 to SENS3 from the time point t1 to the time point t4 may be the sensing operations on the LSB page, the CSB page, and the MSB page, respectively When a memory cell is a TLC, read voltages may include first to seventh read voltages R1 to R7.

According to implementations, when the word line WLx is pre-charged to a level of the read pass voltage Vread in the first setting up operation PBINIT1, the fifth read voltage R5 and the first read voltage R1 may be sequentially applied to the word line WLx according to the descending order H2L while the first sensing operation SENS1 is being performed. While the second sensing operation SENS2 is being performed, the second read voltage R2, the fourth read voltage R4, and the sixth read voltage R6 may be sequentially applied to the word line WLx according to the ascending order L2H. While the third sensing operation SENS3 is being performed, the seventh read voltage R7 and the third read voltage R3 may be sequentially applied to the word line WLx according to the descending order H2L.

Read operations from the time point t3 to a time point t6 may be the read operations performed on the different string select lines and the same word lines described above with reference to FIG. 12. A read order of a fourth sensing operation SENS4 may be the ascending order L2H, because a read order of the third sensing operation SENS3, which is the sensing operation directly previous to the fourth sensing operation SENS4, is the descending order H2L. Thus, while the fourth sensing operation SENS4 is being performed, the first read voltage R1 and the fifth read voltage R5 may be sequentially applied to the word line WLx according to the ascending order L2H.

Read operations from the time point t5 to a time point 8 may be similar to the read operations from the time point t0 to the time point t4. However, read orders of the fourth sensing operation SENS4, a fifth sensing operation SENS5, and a sixth sensing operations SENS6 may be determined as the ascending order L2H, the descending order H2L, and the ascending order L2H, respectively.

Read operations from a time point t9 to a time point t11 may be similar to the read operations from the time point t3 to the time point t6 and the read operations from the time point t5 to the time point t8. During a period from a time point t10 to a time point t11, sensing operations of the ascending order L2H, the descending order H2L, and the ascending order L2H may be performed.

Read operations from the time point t11 to a time point t13 may be the read operations performed on the different string select lines and the different word lines described above with reference to FIG. 15.

According to implementations illustrated in FIG. 16, the first setting up operation PBINIT1 may be performed on the first string select line SSL1. However, it is only an example. According to an address of a sequential read command, the first setting up operation PBINIT1 may be pre-charged from any one selected from among second to eighth string select lines SSL2 to SSL8.

As described above, when a sequential read operation is performed, read operations may be performed on three pages in one string select line, and as the number of the selected string select line increases by one, the read operations on the three pages may be performed, and as the number of the selected string select line increases by one and the number of the selected word line increases by one, the read operations on the three pages may be performed.

Although not shown, according to another implementation, when, during the first setting up operation PBINIT1, a voltage level of the word line WLx is pre-charged to a voltage level lower than a level of the read pass voltage Vread, read operations may be performed according to read orders opposite to the read orders illustrated in FIG. 16.

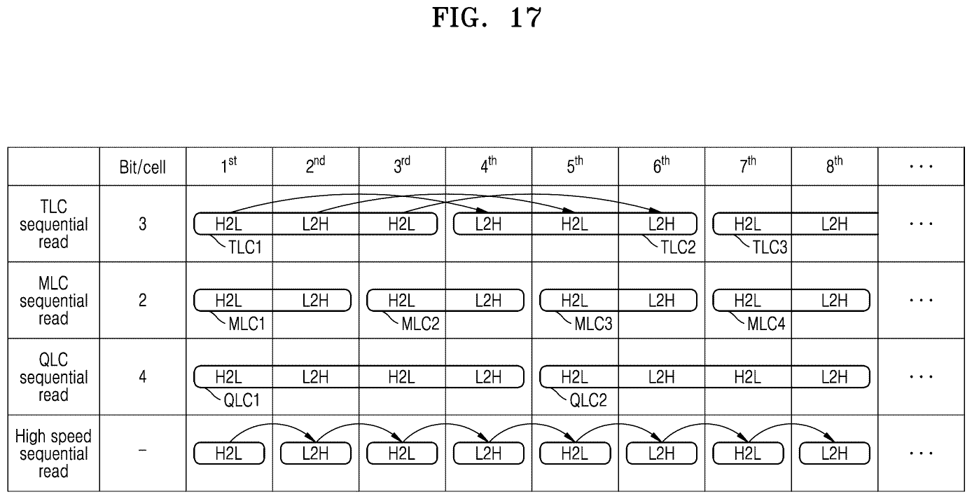

FIG. 17 is a diagram for describing an example of a read order of a sequential read operation according to a type of a memory cell.

Referring to FIG. 17, according to an implementation, the first sensing operation may include determining, with respect to a first memory cell connected to the first selected word line and storing an odd-numbered bit, any one of an ascending order and a descending order as the first read order, and determining, with respect to a second memory cell connected to the first selected word line and storing an even-numbered bit, any one of the ascending order and the descending order as the first read order. The second sensing operation may include determining, with respect to a third memory cell connected to the first selected word line and storing the odd-numbered bit, an order different from the order applied to the first memory cell as the second read order, and determining, with respect to a fourth memory cell connected to the first selected word line and storing the even-numbered bit, the same order as the order applied to the second memory cell as the second read order.

TLC sequential reading (refer to “TLC sequential read” of FIG. 17) may be a sequential read operation on TLCs (a first TLC TLC1, a second TLC TLC2, and a third TLC TLC3) storing three bits per cell. In this case, read operations on the first TLC TLC1 may be performed by alternate read orders of the descending order H2L, the ascending order L2H, and the descending order H2L. Read operations on the second TLC TLC2 after the first TLC TLC1 may be performed by alternate read orders of the ascending order L2H, the descending order H2L, and the ascending order L2H. The read order of a read operation (for example, the read operation on the LSB page) firstly performed may be alternated, whenever the TLC to read is changed. For example, the read order of the read operation (refer to “TLC1” and “1st” of FIG. 17) on the LSB page with respect to the first TLC TLC1 may be opposite to the read order of the read operation (refer to “TLC2” and “4th” of FIG. 17) on the LSB page with respect to the second TLC TLC2. The read order of the read operation on the LSB page with respect to the second TLC TLC2 may be opposite to the read order of the read operation (refer to “TLC3” and “7th” of FIG. 17) on the LSB page with respect to the third TLC TLC3.

MLC sequential reading (refer to “MLC sequential read” of FIG. 17) may be a sequential read operation on MLCs (a first MLC MLC1, a second MLC MLC2, and a third MLC MLC3) storing two bits per cell. Read operations on each MLC may be performed by alternate read orders of the descending order H2L and the ascending order L2H, and the read orders of each MLC may be the same as the descending order H2L first, and then, the ascending order L2H.

QLC sequential reading (refer to “QLC sequential read” of FIG. 17) may be a sequential read operation on QLCs (a first QLC QLC1 and a second QLC QLC2) storing four bits per cell. Similarly to the MLC sequential reading, read operations on each QLC may be performed by alternate read orders of the descending order H2L and the ascending order L2H, and the read orders of each QLC may be the same.

As described above, in a sequential read operation on the memory cells, each of which stores an odd-numbered bit, a pattern of read orders with respect to each memory cell may change. However, in a sequential read operation on the memory cells, each of which stores an even-numbered bit, a pattern of read orders with respect to each memory cell may be constant or the same. Despite the pattern of the read orders, for example, the alternating pattern of the read orders, threshold voltage distribution of the memory cells may not change.

High speed sequential reading (refer to “high speed sequential read” of FIG. 17) may be a sequential read operation performed by alternate read orders of the descending order H2L and the ascending order L2H, regardless of a type of a memory cell.

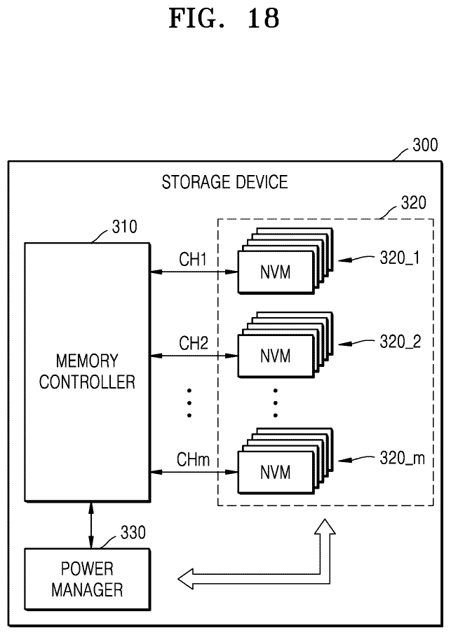

FIG. 18 is a block diagram of a storage device 300 according to implementations. The same descriptions about the storage device 300 as described above with reference to FIGS. 1 to 17 are omitted.

Referring to FIG. 18, the implementations described above with reference to FIGS. 1 to 17 may be applied to the storage device 300. The storage device 300 may be realized as various devices, such as an SSD, a universal flash storage (UFS), and an embedded multi-media card (eMMC). The storage device 300 may be included in a mobile device. The storage device 300 may operate by using a voltage supplied from the outside or a voltage internally charged. The storage device 300 may include a memory controller 310, a plurality of nonvolatile memories 320, and a power manager 330.

The memory controller 310 may communicate with the plurality of nonvolatile memories 320 through a plurality of channels, namely, first to m^{th} channels CH1 to CHm. According to implementations, the memory controller 310 may provide a plurality of commands to the plurality of nonvolatile memories 320 through the first to m^{th} channels CH1 to CHm. For example, the memory controller 310 may issue a plurality of read commands to the plurality of nonvolatile memories 320 in response to read requests from a host.

The plurality of nonvolatile memories 320 may include nonvolatile memories 320_1 connected to the first channel CH1, nonvolatile memories 320_2 connected to the second channel CH2, nonvolatile memories 320_m connected to the m^{th} channel CHm, etc.

The nonvolatile memories connected through each channel may perform operations according to commands, in parallel. According to implementations, each of the plurality of nonvolatile memories 320 may start a read operation at a different time point, in response to a corresponding first read command from among the plurality of read commands. For example, one of the nonvolatile memories 320_1, one 320_2 of the nonvolatile memories 320_2, and one of the nonvolatile memories 320_m may perform read operations, in parallel, according to the read commands. That the operations are performed in parallel may denote that, although at least portions of periods during which the operations are performed may overlap, start points of the operations of the nonvolatile memories may partially overlap or may not overlap. When the start points of the operations of the nonvolatile memories partially overlap each other, the sum of the power or current consumed by the overlapping nonvolatile memories may be combined.

The power manager 330 may manage the power of the storage device 300 such that the power (or current) consumed by the operations performed by the memory controller 310 and/or the plurality of nonvolatile memories 320 does not exceed the power (or current) (or budget) allowable in the storage device 300. According to an implementation, the power manager 330 may be realized as a power management integrated circuit (PMIC).

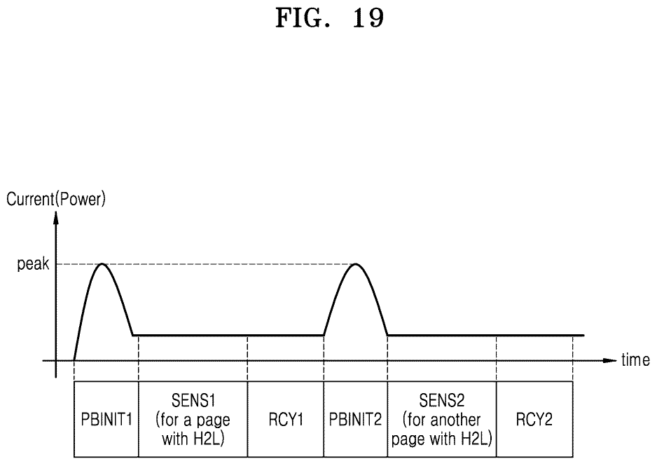

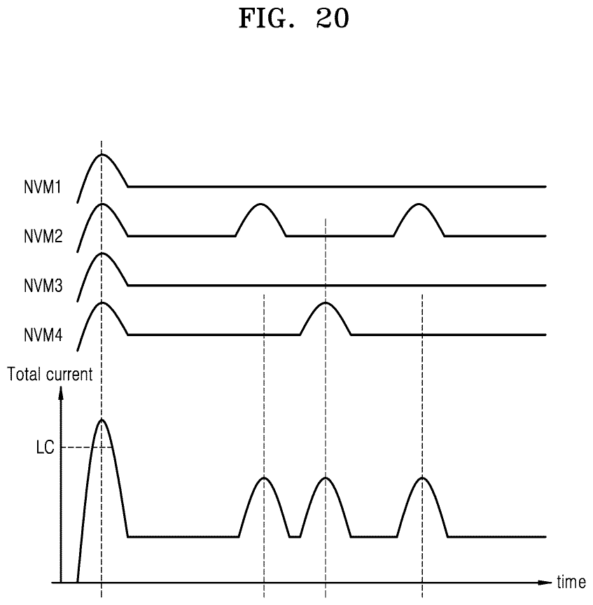

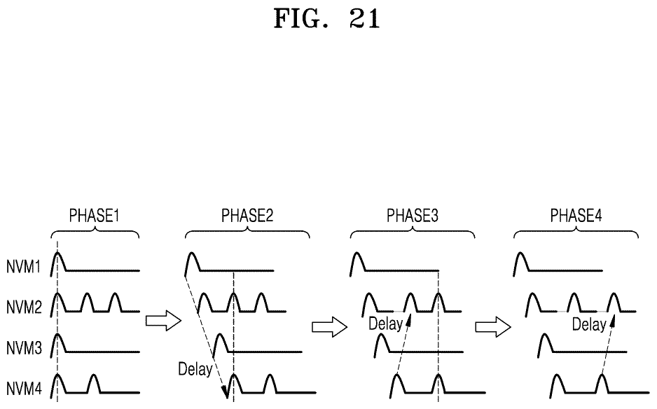

FIG. 19 is an example graph of a current generated by a read operation performed by one nonvolatile memory according to a comparative implementation, FIG. 20 is an example graph of the total current generated by read operations performed by two or more nonvolatile memories according to a comparative implementation, and FIG. 21 is a diagram for describing an example of an operation of managing a timing at which a peak current is generated in a read operation according to a comparative implementation. For convenience of explanation, the comparative implementation is described below based on first to fourth nonvolatile memories NVM1 to NVM4.

Referring to FIG. 19, one nonvolatile memory may perform read operations according to first and second read commands. The read operation according to the first read command may include the first setting up operation PBINIT1, the first sensing operation SENS1 with respect to a page according to a first address of the first read command, and a first recovery operation RCY1. The read operation according to the second read command subsequent to the first read command may include a second setting up operation PBINIT2, a second sensing operation SENS2 with respect to a page according to a second address of the second read command, and a second recovery operation RCY2. A read order of the first and second sensing operations SENS1 and SENS2 may be a default configuration, for example, a descending order H2L. However, the present disclosure is not limited thereto. Each of operations included in the read operations according to the first and second read commands may generate a current and may consume power. A peak current may be generated in each of the first and second setting up operations PBINIT1 and PBINIT2.

Referring to FIG. 20, when each of the first to fourth nonvolatile memories NVM1 to NVM4 performs at least one read operation, the peak current may be generated at least once by the setting up operation in each of the first to fourth nonvolatile memories NVM1 to NVM4 as illustrated in FIG. 20. Also, the currents generated by the read operations of the first to fourth nonvolatile memories NVM1 to NVM4 may be summed. However, with the setting up operations of the first to fourth nonvolatile memories NVM1 to NVM4 overlapping each other, the peak currents of the first to fourth nonvolatile memories NVM1 to NVM4 may be summed to generate the total current equal to or greater than a limit current LC. In this case, some of the first to fourth nonvolatile memories NVM1 to NVM4 may not perform operations, and thus, the requested read performance may not be satisfied.

Referring to FIG. 21, the setting up operations of the first to fourth nonvolatile memories NVM1 to NVM4 may overlap each other in a first phase PHASE1, and thus, the peak currents by the setting up operations may be summed.

To prevent the sum of the peak currents at the first phase PHASE1 from exceeding the limit current LC, a time point to start the read operation of each of the first to fourth nonvolatile memories NVM1 to NVM4 may be delayed at a second phase PHASE2. For example, the setting up operation of the second nonvolatile memory NVM2 may be delayed compared to the setting up operation of the first nonvolatile memory NVM1, the setting up operation of the third nonvolatile memory NVM3 may be delayed compared to the setting up operation of the second nonvolatile memory NVM2, and the setting up operation of the fourth nonvolatile memory NVM4 may be delayed compared to the setting up operation of the third nonvolatile memory NVM3. As a first setting up operation of each of the first to fourth nonvolatile memories NVM1 to NVM4 is delayed, a second setting up operation to be performed by the second nonvolatile memory NVM2 may overlap the first setting up operation to be performed by the fourth nonvolatile memory NVM4. At a third phase PHASE3, the second setting up operation to be performed by the second nonvolatile memory NVM2 may be delayed compared to the first setting up operation to be performed by the fourth nonvolatile memory NVM4. In this case, as the read operation of the second nonvolatile memory NVM2 is delayed, the second nonvolatile memory NVM2 may stop the read operation and stand by or may have an idle state. Also, a third setting up operation to be performed by the second nonvolatile memory NVM2 may overlap a second setting up operation to be performed by the fourth nonvolatile memory NVM4.

At a fourth phase PHASE4, the third setting up operation to be performed by the second nonvolatile memory NVM2 may be delayed compared to the second setting up operation to be performed by the fourth nonvolatile memory NVM4. In this case, as the read operation of the second nonvolatile memory NVM2 is delayed, the second nonvolatile memory NVM2 may stop the read operation and stand by (or the second nonvolatile memory NVM2 may have an idle state).

As described above, the operation of delaying the timing of the read operation may be referred to as peak current management (PCM) or time division PCM (TDPCM). Time points at which peak currents are generated in the first to fourth nonvolatile memories NVM1 to NVM4 may not overlap due to the PCM, and thus, all of the first to fourth nonvolatile memories NVM1 to NVM4 may perform read operations, but time periods to finish the read operations may increase, and thus, latency may occur.

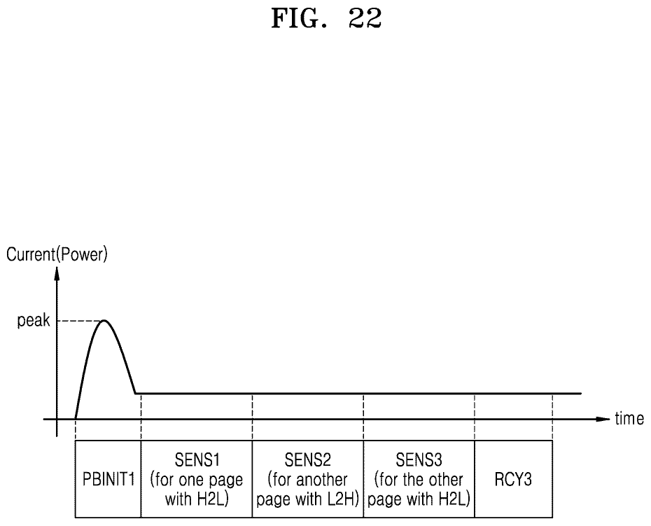

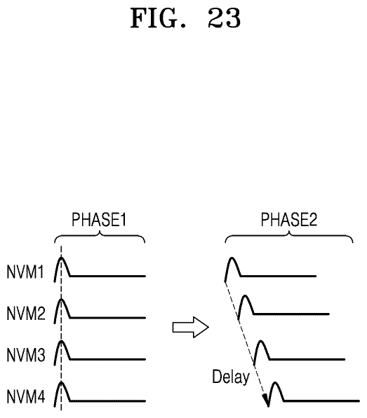

FIG. 22 is an example graph of a current generated by a read operation according to implementations, and FIG. 23 is a diagram for describing an example of an operation of managing a timing at which a peak current is generated in a read operation according to an implementation. For convenience of explanation, implementations are described below based on the first to fourth nonvolatile memories NVM1 to NVM4. The same descriptions as described above with reference to FIGS. 19 and 20 are omitted.

Referring to FIG. 22, each of the plurality of nonvolatile memories 320 according to implementations may omit a recovery operation of a current read command, according to whether or not a subsequent read command is provided before a sensing operation of the current read command, and may determine a read order of a current sensing operation according to a read order of a previous sensing operation. Referring to FIG. 22, first example, the first setting up operation PBINIT1, the first to third sensing operations SENS1 to SENS3, and a third recovery operation RCY3 may be included. The first and second recovery operations may be skipped. In this case, a setting up operation may be performed only once in each of the plurality of nonvolatile memories 320, and a peak current may be generated once for each of the plurality of nonvolatile memories 320.

Referring to FIG. 23, the peak currents of the first to fourth nonvolatile memories NVM1 to NVM4 may be summed at the first phase PHASE1, but PCM may be performed at the second phase PHASE2. Thus, the number of times of the operations of generating the peak current may be reduced, and the number of entry competitions between two or more nonvolatile memories may be reduced during the PCM. Thus, the latency may be reduced, and a sufficient number of nonvolatile memories may perform read operations in parallel, which may lead to improvement of read performance.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An operating method of a nonvolatile memory device, the operating method comprising:
performing, based on a first read command, on a first selected word line, a first sensing operation that starts by a first read order, the first read order indicating an order of applying at least two first read voltages;
based on receiving a second read command before the first sensing operation is finished, finishing the first sensing operation without performing a first recovery operation; and
performing, based on the second read command, on a second selected word line, a second sensing operation that starts by a second read order, the second read order being based on a first address of the first read command and a second address of the second read command.

2. The operating method of claim 1, wherein a first selected string select line corresponding to the first address is a second selected string select line corresponding to the second address,
wherein the second selected word line corresponding to the second address is the first selected word line corresponding to the first address, and
wherein performing the second sensing operation comprises:
determining, as the second read order, a read direction that is different from the first read order;
sequentially applying at least two second read voltages to the second selected word line based on the second read order; and
detecting, through a plurality of bit lines, sensing values based on the at least two second read voltages.

3. The operating method of claim 1, wherein a first selected string select line corresponding to the first address is a second selected string select line corresponding to the second address,
wherein the second selected word line corresponding to the second address is different from the first selected word line corresponding to the first address, and
wherein the operating method comprises, after the first sensing operation is finished, performing a second setting up operation on the first selected word line,
wherein performing the second sensing operation comprises:
after the second setting up operation is finished, sequentially applying at least two second read voltages to the second selected word line based on the second read order; and
detecting, through a plurality of bit lines, sensing values based on the at least two second read voltages.

4. The operating method of claim 3, wherein a period of the second setting up operation is based on a voltage level of the first selected word line at a completion of the first sensing operation.

5. The operating method of claim 1, wherein a first selected string select line corresponding to the first address is different from a second selected string select line corresponding to the second address,
wherein the second selected word line corresponding to the second address is the first selected word line corresponding to the first address, and
wherein the operating method comprises:
after the first sensing operation is finished, performing a second recovery operation on the first selected string select line; and
after the second recovery operation is started, performing a second setting up operation on the second selected string select line,
wherein performing the second sensing operation comprises:
after the second setting up operation is finished, determining, as the second read order, a read direction that is different from the first read order;
sequentially applying at least two second read voltages to the second selected word line based on the second read order; and
detecting, through a plurality of bit lines, sensing values based on the at least two second read voltages.

6. The operating method of claim 1, wherein a first selected string select line corresponding to the first address is different from a second selected string select line corresponding to the second address,
wherein the second selected word line corresponding to the second address is different from the first selected word line corresponding to the first address, and
wherein the operating method comprises:
after the first sensing operation is finished, performing a second recovery operation on the first selected string select line; and
after the second recovery operation is started, performing a second setting up operation on the first selected word line and the second selected string select line,
wherein performing the second sensing operation comprises:
after the second setting up operation is finished, sequentially applying at least two second read voltages to the second selected word line based on the second read order; and
detecting, through a plurality of bit lines, sensing values based on the at least two second read voltages.

7. The operating method of claim 6, wherein the second setting up operation is started from a time point that corresponds to a string select transistor connected to the first selected string select line being turned off during the second recovery operation, and
a period of the second setting up operation is based on a voltage level of the first selected word line at a completion of the first sensing operation.

8. The operating method of claim 1, comprising, before the first sensing operation, performing, based on the first read command, a first setting up operation on a first string select line and a plurality of word lines, wherein performing the first setting up operation comprises applying a set up voltage on the first selected word line,
wherein the first read order is:
a descending order corresponding to a read voltage decreasing from a first value to a second value based on the set up voltage being a third value; or
an ascending order corresponding to the read voltage increasing from the second value to the first value based on the set up voltage being a fourth value, the fourth value being lower than the third value.

9. The operating method of claim 1,
wherein performing the first sensing operation on the first selected word line comprises:
determining, with respect to a first memory cell that is connected to the first selected word line and stores an odd-numbered bit, and as the first read order, one of an ascending order and a descending order; or
determining, with respect to a second memory cell that is connected to the first selected word line and stores an even-numbered bit, and as the first read order, one of the ascending order and the descending order, and
wherein the second selected word line is the first selected word line, and performing the second sensing operation on the second selected word line comprises:
determining, with respect to a third memory cell that is connected to the first selected word line and stores the odd-numbered bit, and as the second read order, an order different from the first read order applied to the first memory cell; or
determining, with respect to a fourth memory cell that is connected to the first selected word line and stores the even-numbered bit, and as the second read order, a same order as the first read order applied to the second memory cell.

10. The operating method of claim 1, comprising performing the first recovery operation, based on a first selected memory block corresponding to the first address being different from a second selected memory block corresponding to the second address,
wherein the second sensing operation is performed after the first recovery operation is finished.

11. A nonvolatile memory device comprising:
a memory cell array comprising a plurality of memory blocks each connected to a plurality of string select lines, a plurality of word lines, and a plurality of bit lines;
a voltage generator configured to provide a voltage to word lines that are connected to a selected memory block of the plurality of memory blocks;
a row decoder configured to select a string select line of the plurality of string select lines that is connected to the selected memory block and a word line of the word lines that is connected to the selected memory block; and
a control logic circuit configured to perform a read operation by controlling, based on a read command, the voltage generator and the row decoder,
wherein the control logic circuit is configured to:
perform, based on a first read command, a first setting up operation on a first selected string select line of the plurality of string select lines and the word lines;
perform, on a first selected word line of the word lines, a first sensing operation that starts by a first read order, the first read order corresponding to an order of applying at least two read voltages; and
perform, based on a second read command after the first read command and on a second selected word line of the word lines, a second sensing operation that starts by a second read order, the second read order being based on a first address of the first read command and a second address of the second read command.

12. The nonvolatile memory device of claim 11, wherein the control logic circuit is configured to, based on a reception timing of the second read command, selectively finish the first sensing operation without a first recovery operation.

13. The nonvolatile memory device of claim 12, wherein the control logic circuit is configured to:
based on receiving the second read command before the first sensing operation is finished, finish the first sensing operation without the first recovery operation; and,
based on receiving the second read command after the first sensing operation is finished, perform the first recovery operation on the first selected string select line and the word lines, and perform, after the first recovery operation is finished, the second sensing operation.

14. The nonvolatile memory device of claim 11, wherein the control logic circuit is configured to selectively determine, based on a voltage level applied to the first selected word line in the first setting up operation, and as the first read order, a descending order or an ascending order.

15. The nonvolatile memory device of claim 11, wherein the control logic circuit is configured to selectively determine, as the second read order, the first read order or an order opposite to the first read order, based on a comparison result between the first selected string select line corresponding to the first address and a second selected string select line corresponding to the second address and a comparison result between the first selected word line and the second selected word line.

16. A storage device comprising:
a plurality of nonvolatile memories each comprising a plurality of string select lines and a plurality of word lines; and
a memory controller configured to send a plurality of read commands to the plurality of nonvolatile memories in response to read requests by a host,
wherein two or more nonvolatile memories of the plurality of nonvolatile memories are configured to:
start, based on a first read command and at different time points, first setting up operations that are performed on a first selected string select line of the plurality of string select lines, and the plurality of word lines;
perform, on a first selected word line of the plurality of word lines, a first sensing operation that starts by a first read order;
based on receiving a second read command subsequent to the first read command before the first sensing operation is finished, finish the first sensing operation without a first recovery operation on the first selected word line; and
perform, on a second selected word line of the plurality of word lines, a second sensing operation that starts by a second read order, the second read order being based on a first address of the first read command and a second address of the second read command.

17. The storage device of claim 16, wherein two or more nonvolatile memories of the plurality of nonvolatile memories are configured to determine, based on the first selected string select line being a second selected string select line that corresponds to the second address and the first selected word line being the second selected word line, and as the second read order, a read direction that is different from the first read order.

18. The storage device of claim 16, wherein two or more nonvolatile memories of the plurality of nonvolatile memories are configured to:
based on the first selected string select line being a second selected string select line that corresponds to the second address and the first selected word line being different from the second selected word line, perform a second setting up operation on the first selected word line, after the first sensing operation is finished; and
perform the second sensing operation, after the second setting up operation is finished.

19. The storage device of claim 16, wherein two or more nonvolatile memories of the plurality of nonvolatile memories are configured to:
based on the first selected string select line being different from a second selected string select line that corresponds to the second address and the first selected word line being the second selected word line, perform a second recovery operation on the first selected string select line, after the first sensing operation is finished;
perform a second setting up operation on the second selected string select line; and
after the second setting up operation is finished, perform the second sensing operation based on the second read order, the second read order having a read direction that is different from the first read order.

20. The storage device of claim 16, wherein two or more nonvolatile memories of the plurality of nonvolatile memories are configured to:
based on the first selected string select line being different from a second selected string select line that corresponds to the second address and the first selected word line being different from the second selected word line, perform a second recovery operation on the first selected string select line, after the first sensing operation is finished;
perform a second setting up operation on the first selected word line and the second selected string select line; and
perform the second sensing operation, after the second setting up operation is finished.
